(19) United States
(12) Patent Application Publication
(10) Pub. No.: US 2022/0373734 A1
(43) Pub. Date: Nov. 24, 2022

(54) INTEGRATED CIRCUIT PACKAGE INTERPOSERS WITH PHOTONIC & ELECTRICAL ROUTING

(71) Applicant: Intel Corporation, Santa Clara, CA (US)

(72) Inventors: Benjamin Duong, Phoenix, AZ (US); Sandeep Gaan, Chandler, AZ (US); Srinivas Pietambaram, Chandler, AZ (US); Wenchao Li, Gilbert, AZ (US); Kristof Darmawikarta, Chandler, AZ (US); Ankur Agrawal, Chandler, AZ (US); Ravindranath Mahajan, Chandler, AZ (US)

(73) Assignee: Intel Corporation, Santa Clara, CA (US)

(21) Appl. No.: 17/323,881

(22) Filed: May 18, 2021

(51) Int. Cl. G02B 6/12; H01L 25/16; H01L 23/00; H01L 23/31; H01L 23/367; H01L 23/498; H01L 21/48; H01L 21/56; G02B 6/13

(52) U.S. Cl. CPC G02B 6/12004; H01L 25/167; H01L 24/16; H01L 23/3121; H01L 23/3672; H01L 23/49827; H01L 21/4853; H01L 21/486; H01L 21/565; G02B 6/13; H01L 2224/16227; H01L 2924/12042; H01L 2924/12043; H01L 2924/1431; H01L 2924/1434; H01L 2924/1903; G02B 2006/12061; G02B 2006/12121

(57) ABSTRACT

IC chip package with silicon photonic features integrated onto an interposer along with electrical routing redistribution layers. An active side of an IC chip may be electrically coupled to a first side of the interposer through first-level interconnects. The interposer may include a core (e.g., of silicon or glass) with electrical through-vias extending through the core. The redistribution layers may be built up on a second side of the interposer from the through-vias and terminating at interfaces suitable for coupling the package to a host component through second-level interconnects. Silicon photonic features (e.g., of the type in a photonic integrated circuit chip) may be fabricated within a silicon layer of the interposer using high temperature processing, for example of 350° C., or more. The photonic features may be fabricated prior to the fabrication of metallized redistribution layers, which may be subsequently built-up within dielectric material(s) using lower temperature processing.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

One or more IC chips within a package typically communicate with a host component, or with each other, through electrically conductive metal features built up on an interposer, or package substrate. Such a package routing structure may include a redistribution layer (RDL) embedded within a package dielectric material, such as an epoxy or other organic material. Packaged IC chips may be attached to a first side of the package routing structure, for example with “first-level” interconnects (FLI). A second side of the package routing structure may terminate at interfaces that are to further couple the package routing to a host component, for example through “second-level” interconnects (SLI). For metal conductors, signal loss increases significantly as signal frequency increases and/or the distance traveled increases. Furthermore, the package routing structure needed for die-to-die communication becomes increasingly complex as more dies/chiplets are added to a single package.

A photonic integrated circuit (PIC) includes integrated photonic devices or elements. PICs are preferred to optical systems built with discrete optical components and/or optical fiber because of the more compact size, lower cost, heightened functionality, and performance of PICs. PICs utilize an optical I/O interface that includes an optical transmitter and/or an optical receiver coupled to one or more photonic waveguides that propagate light within the PIC. Among PICs, silicon photonics (SiPh) technology continues to gain market share because of clear advantages in terms of manufacturability and scalability. For example, on-chip silicon waveguides have minimum dimensions typically under a micrometer, and may terminate with an optical fiber coupler suitable for coupling the PIC waveguides to optical fibers having diameters on the order of a hundred microns.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods of fabricating a package with an interposer including silicon photonic and electrical routing, in accordance with some embodiments;

FIGS. 2, 3, 4, 5, 6 and 7 illustrate cross-sectional views of a package interposer as selected operations of package interposer fabrication and assembly are practiced, in accordance with some embodiments;

FIG. 8, 9 illustrate cross-section views of a package assembly including IC chips attached to a package interposer, in accordance with some embodiments;

FIG. 10 illustrates a system including a multi-chip package with an integrated SiPh waveguide, in accordance with some embodiments;

FIGS. 11A and 11B illustrate plan views of systems including a multi-chip package interconnected to an interposer with SiPh routing, in accordance with some embodiments;

FIGS. 12, 13 and 14 illustrate isometric sectional views of a package interposer comprising a SiPh waveguide device as selected operations of package interposer fabrication are practiced in accordance with some embodiments;

FIG. 15 illustrates a mobile computing platform and a data server machine employing a package with an interposer including photonic and electrical routing, in accordance with embodiments; and

FIG. 16 is a functional block diagram of an electronic computing device, in accordance with some embodiments.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

IC packages including an IC chip coupled to an electrical routing structure that includes both metallization features of a redistribution layer (RDL) and silicon-based photonic (SiPh) features are described herein. The photonic features include at least a silicon waveguide and may further comprise electro-optical devices, such as a photodetector(diode) laser(diode) emitter, or optical modulator. The photonic features may be formed within a layer of silicon on a first side of an interposer core, and routed around electrical through-vias that pass through a thickness of the core. An active face of one or more IC chips may be attached to the first side of the interposer with electrical I/O and/or our power supply routing conveyed by the through-vias to RDL features on a second side of the interposer core.

The silicon photonic features may be embedded within a first dielectric material. As further described below, the photonic features may be fabricated early in a panel level or wafer level processing (WLP) flow with the use of thin film processing techniques that may leverage high temperatures, for example greater than 350° C. Subsequent to formation of the photonic features, RDL metallization features may be built up, along with a second dielectric material, for example to supply power to one or more IC chips. IC chips may be attached to a first side of the interposer, for example with FLI, over the photonic features. As further described below, additional operations may then be performed once the IC chip is attached. The packaged IC may then be assembled onto a host board, for example with SLI.

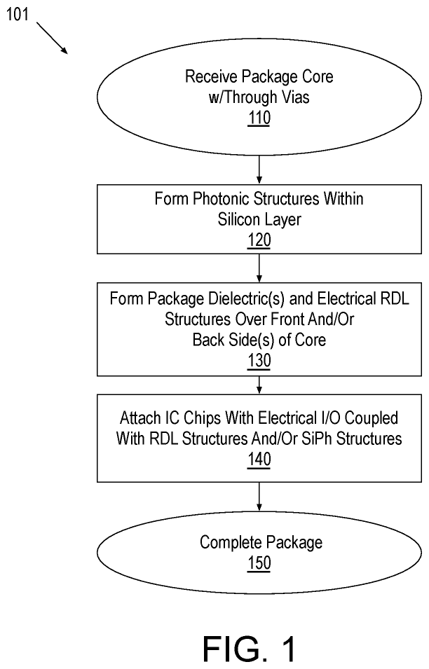

FIG. 1 is a flow diagram illustrating methods 101 for fabricating a package interposer with SiPh features and electrical routing features, in accordance with some embodiments. Methods 101 begin at input 110 with the receipt of a package substrate core suitable for thin film processing. In an exemplary embodiment, the substrate core is substantially planar and dimensioned in thickness and lateral area so as to be a suitable support for wafer-level, or panelized, processing, of multiple packages that are to be arrayed over a working surface of the substrate core. As further described below, the substrate core may comprise one or more material layers. Various material layers of a substrate core may be retained within a final singulated package, or separated from a final package as part of a sacrificial carrier. Electrically conductive through-vias extend through a thickness of the substrate core retained in the final package, for example to convey electrical I/O signals and/or power through the substrate core.

Methods 101 continue at block 120 with the fabrication of photonic structures within a silicon material layer. The photonic structures are fabricated in alignment with the electrical through-vias in the substrate core. For example, photonic structures may be placed in locations where there are no electrical through-vias. As described further below, the silicon material layer may be received as a material layer of the core substrate. Alternatively, the silicon material layer may be affixed, or deposited upon the core substrate at block 120. The photonic structures fabricated into the silicon material utilize refractive index contrast between the silicon and a cladding material (e.g., silicon dioxide) to confine optical modes within the structures, and therefore are referred to as silicon photonic (SiPh) structures. Any of the fabrication methods known to be suitable for forming SiPh structures in a photonic integrated circuit (PIC) may be practiced at block 120. As such, any SiPh structure that can be fabricated in a PIC may be fabricated over the substrate core at block 120 using similarly thin film processing techniques. In exemplary embodiments, the SiPh structure fabricated at block 120 includes at least an optical waveguide (WG), and may further comprise electrically active structures with one or more electrical terminals, such as an electro-optical absorber (EOA), a photodiode (PiN photodetector), or laser emitter. Fiber array alignment features (e.g., v-grooves) may also be fabricated at block 120 in preparation for coupling the optical waveguides to an off-interposer optical source/sink.

In advantageous embodiments, SiPh structures are fabricated prior to the formation of any organic package dielectric and RDL features. With such a sequence, the SiPh structures may be freely fabricated with processes unconstrained by material limitations associated with the package dielectric and/or RDL metallization features. For example, package dielectric may comprise an organic molding compound, spray-on dielectric, or dry film laminate material, which may decompose at some temperature threshold that would otherwise constrain fabrication of SiPh structures. In the absence of package dielectric and/or RDL features, any number of additive or subtractive thin film processes and chip bonding processing may be practiced at block 120 to fabricate SiPh structures.

As described further below, block 120 may entail the deposition of silicon, subtractive patterning (e.g., etching) of silicon, or impurity doping of silicon, as well as the attachment of a hybrid laser emitters and/or photodetectors (PD) comprising a semiconductor material other than silicon (e.g., III-V compounds). The fabrication of SiPh structures at block 120 further includes the deposition of an optical cladding material that provides good refractive index contrast with the silicon material. In exemplary embodiments, silicon dioxide is deposited at block 120 as a cladding of the SiPh structures. One or more of these fabrication processes are performed at a temperature of at least 350° C. Such high temperature processing may be advantageous for at least the deposition of the optical cladding material, for example enabling the deposition of SiO₂ with desirable composition(s) and/or layer thickness(es). For embodiments where the SiPh structures include electrically active optical devices, contact metallization to one or more terminals of the electrical active optical devices may also be fabricated at block 120. Any photolithographic patterning, thin film etching, and thin film metallization deposition (e.g., physical or chemical vapor deposition, or plating) processes may be practiced to form SiPh contact metallization features.

With SiPh structures over one (e.g. top or front) side of the substrate core, methods 101 continue at block 130 where an electrical routing structure is fabricated over a second (e.g., bottom or back) side of the core, opposite the SiPh structures. Such electrical routing may be fabricated with lower temperature processing (e.g., less than 350° C., and typically 120-200° C.) performed while the SiPh structures are protected, for example with any sacrificial protective film. In the illustrated example, methods 101 continue at block 130 where electrically conductive RDL features are formed within one or more package dielectric materials built-up over at least the second side of the core. One or more of these RDL features may be electrically coupled to one or more of the through-vias passing through the core. Any number of levels of RDL features may be formed at block 130 with a top level terminating at features that are suitable for interconnecting to a host component with second-level interconnects (e.g., solder features).

In some further embodiments, the RDL fabrication techniques practiced at block 130 may also extend the electrical routing structure on a top side of the core, for example to extend electrical routing up from the through-vias within the core and/or up from SiPh device terminal metallization. This “front-side” RDL fabrication may be practiced before fabricating any “back-side” RDL structures (i.e., before applying a protective film over the front-side), or may be practiced after fabricating back-side RDL structures (i.e., after removing a protective film from the front-side).

With both SiPh and RDL structures present, the core substrate is suitable as an interposer for a IC chip package to which one or more IC chips are attached. At block 140, one or more IC dies are coupled to the electrical routing structure on the front-side of the substrate core, for example with a first-level interconnect chip attachment process. One or more of the IC chips may be electrically coupled to one or more of the SiPh structures, either through the contact metallization fabricated at block 120, or through one or more of RDL features fabricated at block 130. The IC chip attachment also electrically couples the chip(s) to one or more of the through-vias (either through the contact metallization fabricated at block 120, or through one or more of RDL features fabricated at block 130). As described further below, for multi-chip embodiments the SiPh structures may optically interconnect I/O ports of two or more IC chips within a package.

Following IC chip attach, one or more dielectric materials may be formed over a top of the IC chip and/or between IC chips of a multi-chip package. For example, an overmold process, dry film lamination, or spin-on/spray-on dielectric process may be performed at output 150 to at least partially encapsulate the IC chip(s) within the package. Following completion of the package, the workpiece may be singulated from the panel or wafer to generate singular IC device packages that include IC chip(s) coupled to SiPh devices integrated within the package electrical routing structure. A singulated package may then be further assembled onto a host component, such as a motherboard, and a fiber array unit comprising a plurality of optical fibers (e.g., single mode fibers) may be attached to the package with the fibers optically coupled to the SiPh devices of the package interposer.

Notably, the blocks illustrated in FIG. 1 show an exemplary ordering of operations that may be altered without deviating from scope of the embodiments described herein. For example, electrical RDL structures may be built-up on a (back)side of the interposer core after IC chip attachment.

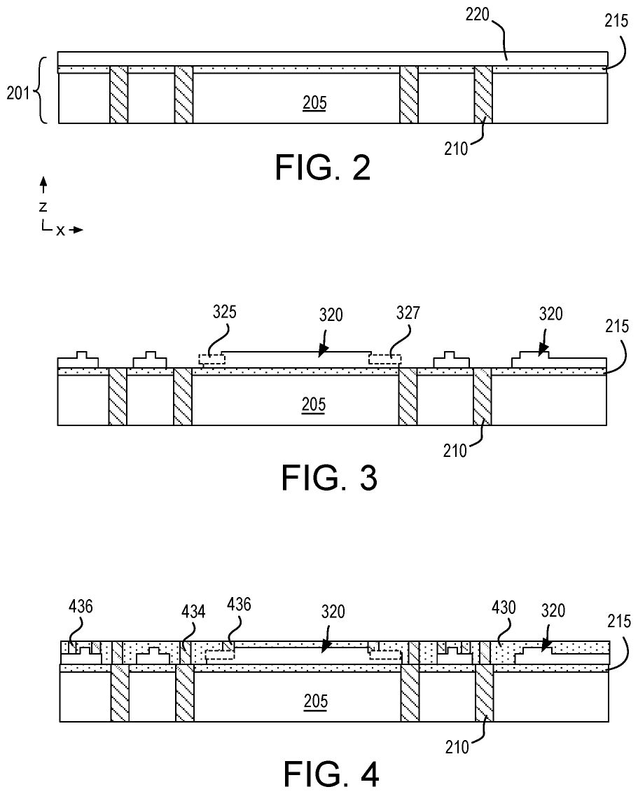

FIG. 2-7 illustrate cross-sectional views of a package interposer as selected operations of a package interposer fabrication process are practiced, in accordance with some embodiments. The structures illustrated in FIG. 2-7 may be fabricated according to methods 101, for example. Alternatively, methods other than 101 may be employed to fabricate the structures illustrated in FIG. 2-7. The cross-sectional views shown in FIG. 2-7 illustrate one package, but any number of such packages may be fabricated in parallel with wafer-level or panel-level processing.

FIG. 2 illustrates an exemplary substrate core 201, which includes a bulk layer 205 and a silicon layer 220. In some embodiments, bulk layer 205 is also silicon, and may be substantially monocrystalline silicon. An insulator layer 215 is between bulk layer 205 and silicon layer 220. For some such embodiments, substrate core 201 is a semiconductor-on-insulator (SOI) substrate further comprising an insulator layer 215 of silicon dioxide (SiO₂) between a bulk layer 205 of monocrystalline silicon and a silicon layer 220 that is also substantially monocrystalline. In some alternative embodiments, bulk layer 205 is glass. Glass substrates have flatness comparable to that of silicon wafers, can have very large dimensions suitable for large format panels, and are typically less expensive than SOI wafers. For some embodiments, such as those where bulk layer 205 is glass, insulator layer 215 may include a material other SiO₂, such as silicon nitride (SiNₓ) or silicon oxynitride (SiOₓN_{y}), to improve adhesion. However, a layer of SiO₂ between such a layer and silicon layer 220 is advantageous for good refractive index contrast.

Silicon layer 220 may be received as part of a preform, such as an SOI wafer, or silicon layer 220 may be formed over a bulk layer 205 that initially lacks silicon layer 220. For example, in some embodiments where bulk layer 205 is glass, silicon layer 220 may be deposited over bulk layer 205. For example, both of insulator layer 215 and silicon layer 220 may be deposited by chemical vapor deposition (CVD). For such embodiments, silicon layer 220 is polycrystalline, rather than monocrystalline. In other embodiments, silicon layer 220 is transferred from a donor with any suitable layer transfer process. For example, silicon layer 220 may be separated from an SOI wafer donor are bonded to insulator layer 215.

As further illustrated in FIG. 2, a plurality of electrical through-vias 210 extend though a thickness of substrate core 201. In the illustrated example, through-vias 210 extend through an entirety of bulk layer 205, and contact insulator layer 215. In some examples, through-vias 210 extend entirely through insulator layer 215 and are in contact with silicon layer 220. Through-vias 210 may also extend entirely through silicon layer 220, or may not extend through insulator layer 215. Through-vias 210 are electrically conductive, and may comprise one or more metals. In some examples, through-vias 210 comprise predominantly copper (Cu), which may be plated into through-holes etched into bulk layer 205, for example according to any through-substrate via (TSV) process capable of minimum TSV pitches in the range of 10-100 μm.

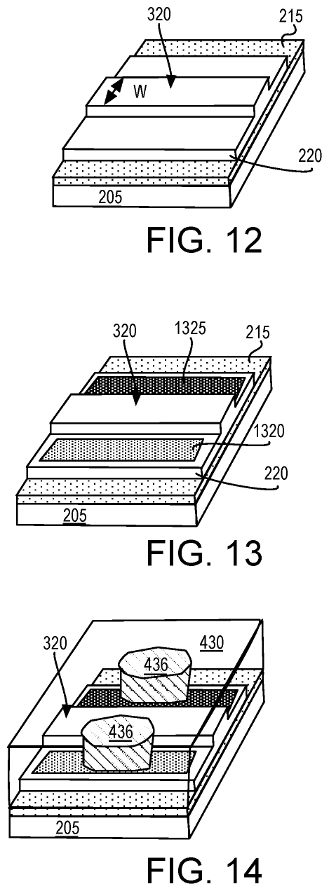

FIG. 3 illustrates a patterning of photonic device structures into silicon layer 220. The photonic structures include at least an optical waveguide 320. Optical waveguide 320 may have any architecture known to be suitable, such as, but not limited to, a rib or ridge waveguide, for example of the type further illustrated in FIG. 12. Optical waveguide 320, along with any other optical device structures may be patterned by first applying a photoresist material over the silicon layer, lithographically defining a pattern into the photoresist, and etching away at least a partial thickness of the silicon layer according to the photoresist pattern. After stripping the photoresist, a planar optical waveguide 320 extends over insulator layer 215 along some predetermined route. Notably, optical waveguide 320 and other SiPh structures generally have sub-micron critical dimensions. For example, a transverse width W of waveguide 320 may range from 150 nm to 400 nm. At such small dimensions, waveguide 320 can be readily routed through the multi-micron pitch of through-vias 210 (FIG. 2).

In addition to optical waveguide 320, SiPh features for electro-optical devices such as a Mach-Zhender interferometer (MZI), EOA, MRR, or MRO may be fabricated into silicon layer 220 (FIG. 3). In some embodiments, portions of the SiPh structures are ion implanted/doped to for electrically active optical devices. Following the implantation, a rapid thermal and/or excimer laser anneal may be practiced to form P-type and/or N-type regions within the photonic structures. For example, as further illustrated in FIG. 13, an N-type region 1320 including N-type impurities (e.g., P, As, Sb) and a P-type region 1325 including P-type impurities (e.g., B) are formed within a portion of silicon layer 220, laterally adjacent to optical waveguide 320.

As further illustrated by dashed outlines in FIG. 3, a hybrid laser 325 and/or a hybrid photodetector (PD) 327 may be mounted over different regions of optical waveguide 320 and/or over portions of other SiPh structures. Hybrid laser 325 and hybrid PD 327 is referred to as “hybrid” because they each include a semiconductor other than silicon, such as, but not limited to a III-V compound semiconductor material. Hybrid laser 325 and PD 327 are prefabricated chips/chiplets, that are bonded to a surface of a SiPh structure. For a detailed description of a hybrid laser 325 and/or hybrid PD 327 in the context of a PIC chip, the interested reader is referred to co-assigned/owned applications directed specifically at such subject matter. A salient distinction however is that hybrid laser 325, hybrid PD 327, or any other hybrid electro-optical element is bonded to a SiPh structure integrated onto substrate core 201 rather than into a PIC chip.

As illustrated in FIG. 4, a cladding of dielectric material 430 may be formed over the SiPh structures. In some embodiments, dielectric material 430 is a silicon-based dielectric comprising predominantly silicon and at least one of either oxygen (e.g., SiO₂) or nitrogen (e.g., Si₃N₄). Dielectric material 430 may also be a carbon-doped silicon dioxide (CDO). Silicon-based dielectric materials may be deposited by one or more of CVD or PECVD, for example. Such deposition techniques are known to produce an excellent insulator layer with a thickness that can be readily controlled to within a few nanometers of wafer-level uniformity. To achieve good insulator material quality (e.g., low electrical leakage, high break down voltage, good index contrast etc.) and uniformity, CVD and PECVD techniques may entail elevated processing temperatures, for example of 350° C., or more. Hence, at the this stage, the workpiece is ideally suitable for processing through any equipment and/or or deposition processes that might be employed in a wafer fab.

In other embodiments, dielectric material 430 may be any molding compound, spin-on material, or dry film laminate material that has a refractive index approximately equal to that of SiO₂ (i.e., suitable as a good optical cladding). Dielectric material 430 may be introduced wet/uncured into a cast and then dried/cured. Alternatively, dielectric material 430 may be introduced as a semi-cured dry film that is deformed around SiPh structures, and then fully cured. Dielectric material 430 may therefore be other than a silicon-based material, such as, an epoxy resin, phenolic-glass, or a resinous film such as the GX-series films commercially available from Ajinomoto Fine-Techno Co., Inc. In some specific examples, dielectric material 430 is a bisphenol-A epoxy resin, for example including epichlorohydrin. In other examples, dielectric material 430 is a bisphenol-F epoxy resin (with epichlorohydrin). In other examples, dielectric material 430 is an aliphatic epoxy resin, which may be monofunctional (e.g. dodecanol glycidyl ether), difunctional (butanediol diglycidyl ether), or have higher functionality (e.g. trimethylolpropane triglycidyl ether). In still other examples, dielectric material 430 is a glycidylamine epoxy resin, such as triglycidyl-p-aminophenol and N,N,N′,N′-tetraglycidyl-bis-(4-aminophenyl)-methane. Although such polymeric materials may decompose at high processing temperatures and may not offer the same electrical and/or optical properties as a silicon-based dielectric, these materials may offer a number of advantages associated with semi-additive build-up techniques.

FIG. 4 further illustrates a first level of electrical routing that includes conductive vias 434 landing on, or otherwise intersecting, through-vias 210. The first level of electrical routing also includes conductive vias 436 landing on, or otherwise intersecting an electrically active SiPh structure. Vias 436 may intersect P/N impurity doped regions of an electrically active SiPh structure and/or may intersect terminals of a previously mounted hybrid laser 325 or hybrid PD 327.

In some exemplary embodiments, conductive vias 434, 436 are formed by patterning openings into dielectric material 430 (e.g., with a masked reactive ion etch process or laser drilling process), and filling the openings with a metallization. The metallization may be plated or vapor deposited. The composition of the metal(s) deposited may be predominantly copper (Cu). In other examples, the metal deposited is predominantly aluminum (Al), cobalt (Co), nickel (Ni), tungsten (W), tantalum (Ta), titanium (Ti), ruthenium (Ru), manganese (Mn), or platinum (Pt). In other embodiments, a nitride, carbide, or silicide of any of the above metals may deposited. Following metal deposition, any overburden may be polished over to planarize conductive vias 434, 436 with a surface of dielectric material 430.

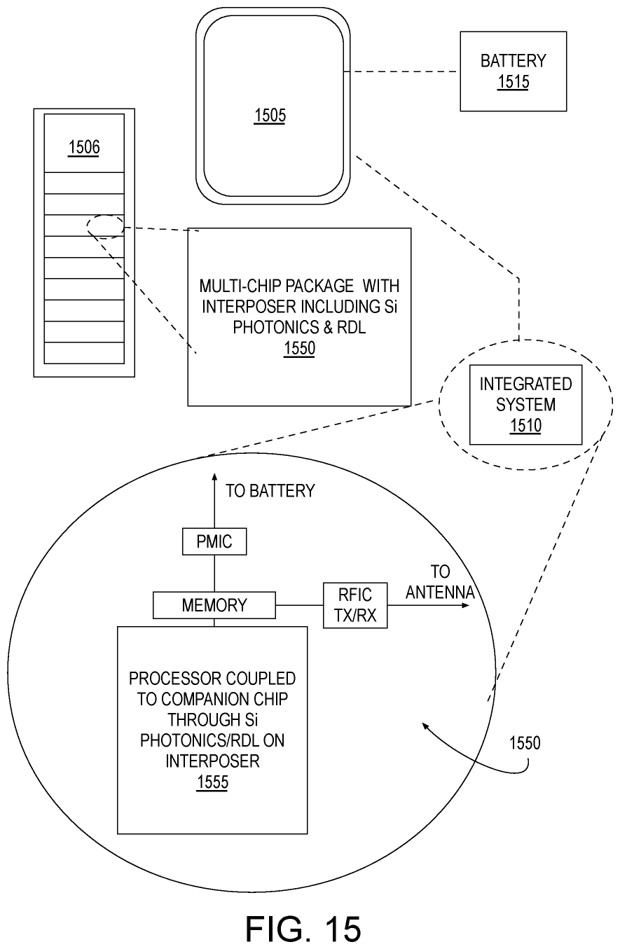

FIG. 14 further illustrates an example of conductive vias 436 landing on P-type and N-type regions 1320, 1325 adjacent to optical waveguide 320. Although this example illustrates metallization features landing on silicon regions that were previously impurity doped, ion implantion/doping may also be performed as part of the metallization process, for example with P/N type impurities being implanted into the openings for conductive vias 436 just prior to the deposition of a metal.

The size of the conductive vias 436 may vary, with exemplary via diameters being 0.5-1 μm for a micro ring oscillator having a diameter of ˜10-1 μm. Although only one level of electrical routing is illustrated in FIG. 4, any number of levels of electrical routing may be fabricated over the SiPh structures. Conducive via diameters and pitches may therefore be scaled between dimensions suitable for SiPh structures and through-vias, to dimensions and pitches suitable for first-level interconnects to an IC die.

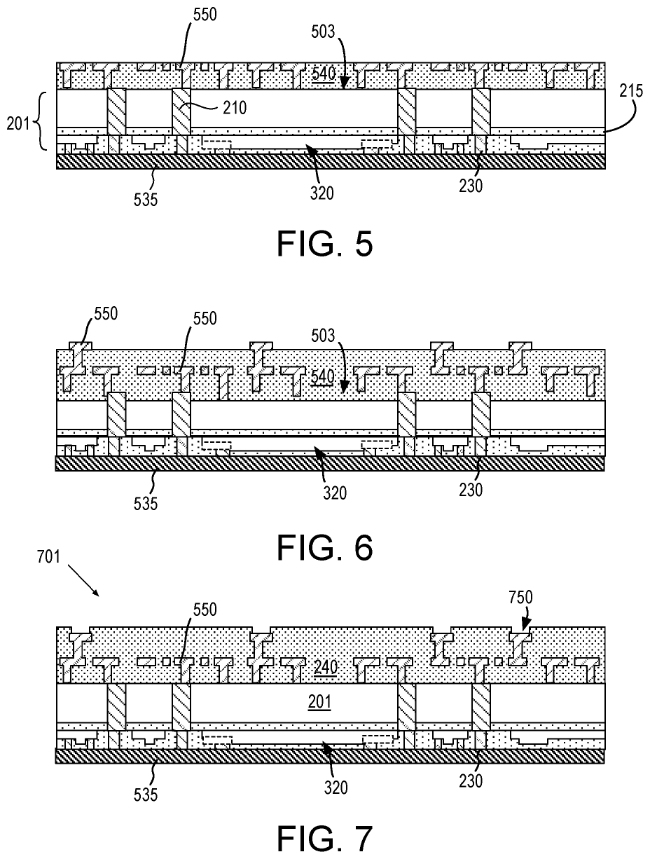

Following fabrication of the SiPh structures and front-side metallization, electrical routing suitable for interconnecting to a package host is built-up on the back-side of the substrate core. As further illustrated in FIG. 5, any suitable protection film 535 may be placed over the SiPh layer to protect front-side features from handling during the build-up of organic dielectric material 540 and RDL features 550 over core backside 503. With fabrication of the SiPh completed, RDL feature fabrication may be limited to processes performed at temperatures less than 350° C. (e.g., 120-200° C.). At least some of RDL features 550 land on, or otherwise intersect through-vias 210 for power delivery and off-interposer I/O through the backside of substrate core 201. Electrical routing on the backside can be formed by practicing an organic build-up processes as organic dielectric will adhere to either silicon or glass substrate materials.

Dielectric material 540 may be applied as a molding compound, a spin-on material, or dry film laminate material. Dielectric material 540 may therefore be other than a silicon-based material, such as any of epoxy resins, phenolic-glasses, or resinous films described above. Openings are then patterned in dielectric material 540, for example with any technique suitable for the particular composition. For embodiments where dielectric material 540 is photosensitive, a lithographic process may directly pattern dielectric material 540. Alternatively, a photolithographic masking process may be performed and dielectric material 540 etched according to the mask. In other embodiments, openings may be ablated, for example with a laser.

Conductive RDL features 550 may be formed with an additive or semi-additive process, for example. In some embodiments, RDL features 550 are formed by first depositing a seed layer (e.g., Cu) and then forming a plating resist mask (not depicted) over the seed layer. With an electrolytic deposition process, Cu is plated upon the seed layer wherever the resist mask is absent. Following the plating process, the plating resist and seed layer may be stripped to arrive at the structure illustrated in FIG. 5.

As further illustrated in FIG. 6, multiple levels of RDL features 550 may be built-up over core back side 503. With each level, additional dielectric material 540 may be applied over RDL features 550. Openings in the additional dielectric material 540 may then be filled with another iteration of a plating process to terminate the electrical routing at second-level interconnect interfaces 750, shown in FIG. 7. Although two levels of RDL features are illustrated, a cycle including package dielectric application, patterning of the package dielectric, and plating of conductive RDL features may be repeated any number of times to build-up any number of levels of conductive redistribution layer features within the electrical routing structure.

With the electrical routing structure terminating at second-level interconnect interfaces, the package interposer is substantially complete and ready for one or more IC chips to be attached to the first-level interconnect interfaces. If not previously attached, hybrid laser and/or PD chiplets can also be attached at this point to further prepare the package interposer for the assembly of ASICs that are to couple to the SiPh structures and the remainder of the FLI. For embodiments where laser and/or PD chiplets are attached at this point, one or more additional levels of RDL metallization features built-up with package dielectric material may provide electrical contact to terminals of the laser or PD.

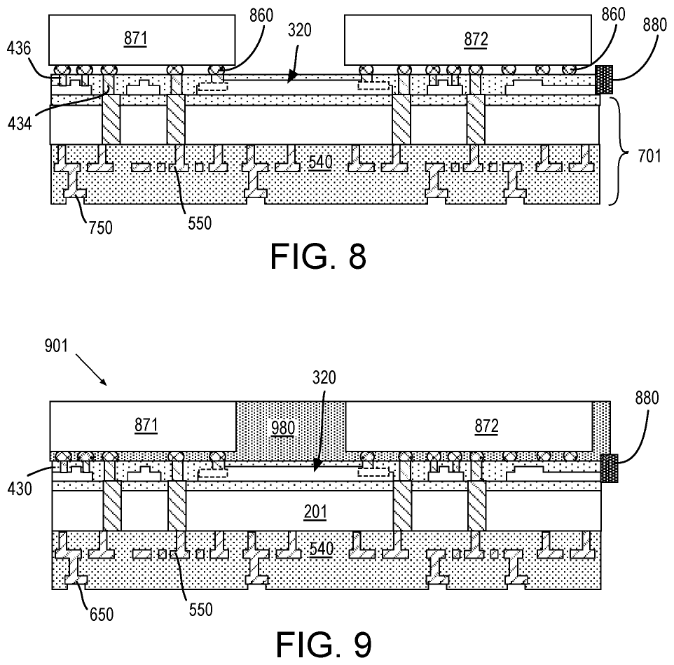

FIGS. 8 and 9 further illustrate cross-sectional views through a portion of a workpiece including one package interposer 701 substantially as fabricated according to FIG. 2-7. In FIG. 8, IC chips 871 and 872 have been attached with FLI features 860 to a first side of a package interposer that includes an optical routing structure integrated with an electrical routing structure. In the example shown, two IC chips 871, 872 are illustrated for a multi-chip package. Optical waveguide 320 is coupled to both IC chip 871 and IC chip 872. Any number of IC chips may be attached to a single package interposer with one or more SiPh structures coupled to any number of the IC chips. As further illustrated, one or more FLI features 860 are electrically coupled to vias 436, which interconnect an IC chip to a terminal of an electrically active SiPh structure. Other FLI features 860 are electrically coupled to through-vias 210, which are further coupled through RDL features 550 to second-level interconnect interfaces 750.

In some embodiments, IC chip 871 and/or IC chip 872 includes microprocessor circuitry. The microprocessor circuitry may be operable, for example, to execute instructions of a real-time operative system (RTOS). In some further embodiments, at least one of IC chip 871, 872 is operable to execute one or more layers of a software stack that controls radio (wireless) functions. In one exemplary embodiment, at least one of IC chip 871, 872 includes a digital baseband processor, or baseband radio processor (BBP) suitable for use within a mobile phone, or other wireless/mobile device. In other embodiments, at least one of IC chips 871, 872 is operable as an electronic memory while at least another of IC chips 871, 872 is operable to execute instructions of a RTOS.

Any technique known to be suitable for positioning an IC chip onto a package substrate may be employed to attached IC chips 871, 872. As one example, a pick-and-place machine may pick-and-place IC chips 871, 872 onto package interposer 701. In some examples, FLI features 860 comprises solder. The solder may be in the form of solder balls, for example, that may be attached according any known process such as a controlled heat treatment that partially reflows the solder. Alternatively, the solder features may be studs, pillars or microbumps comprising a conductive material (e.g., solder paste). FLI 860 may further comprise one or more layer of under-bump metallization (UBM) that may, for example, include gold and/or nickel.

One or more off-chip/on-interposer optical components 880, such as an optical fibers and/or a laser source can be attached, for example to v-grooves aligned to optical waveguide 320, or other SiPh structures of the interposer that were previously fabricated (e.g., at block 120 of methods 101). Optical components 880 may be attached with epoxy or another structural adhesive at the edge of package interposer 701. For example a fiber array may be passively aligned to waveguide 320 by placing fibers of the array into v-grooves etched in silicon interposer 201. Optical components 880 may provide a means of both off-interposer (e.g., to another IC chip assembled to a different interposer) and on-interposer (i.e., between IC chips on the same interposer) optical communication.

As further illustrated in FIG. 9, a dielectric material 980 may be applied over IC chips 871, 872 (and any optical components 880). Dielectric material 980 may have substantially the same composition as one or more of dielectric materials 430 and 540. Alternatively, dielectric material 980 may have a composition that differs from one or more of dielectric materials 430, 540. In some embodiments, dielectric material 980 is a mold compound applied, for example, with an overmold process. In the illustrated example, mold compound completely planarizes IC chips 871, 872, filling spaces between adjacent IC chips and over optical waveguide 320. In other embodiments, dielectric material 980 is a build-up dielectric applied, for example, with a dry film laminate process or a liquid application process (e.g., spin-on). For such embodiments, dielectric material 980 may substantially planarize IC chips 871, 872 completely covering optical waveguide 320, substantially as illustrated. If desired, a lid (not depicted) may then be affixed over dielectric material 980 to substantially complete package assembly 901.

Although dielectric material 980 is illustrated as being applied after the attachment of off-chip/on-interposer optical components 880, in alternative embodiments, optical components 880 (e.g., a fiber array unit) may be instead attached after dielectric material 980 is applied. For example, a portion dielectric material 980 may be removed from over v-grooves that were previously patterned into interposer 201. The fiber array unit may then be attached to the exposed v-grooves.

Package assembly 901 is then ready for electrical interconnection to a host component, such as a PCB, through any suitable second level interconnect features. In some alternative embodiments, a side of the electrical routing structure opposite the IC chips is now processed (e.g., substantially as described above) to form the RDL features terminating at an the second-level interconnect interfaces. In other words, the RDL build-up described above may be completed following chip attach rather than fabricating such structures prior to chip attach.

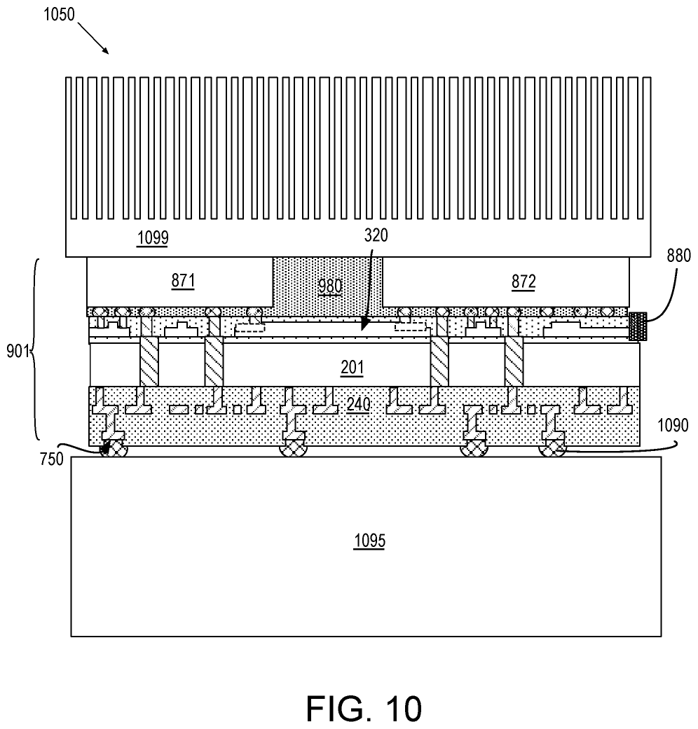

IC package routing that integrates SiPh structures in accordance with one or more of the embodiments described above may be further integrated into a system that includes a host component to which the package electrical routing is attached. FIG. 10 illustrates a system 1050 including IC chip package 901 interconnected to a host component 1095, in accordance with some embodiments. In some examples, host component 1095 is a PCB, for example including one or more interconnect trace levels laminated with one or more glass-reinforced epoxy sheets, such as, but not limited to FR-4. As depicted, IC package 901 includes IC chips 871, 872, each of which further includes an IC. IC package 901 further includes at least optical waveguide 320, substantially as described above.

In some examples, SLI 750 comprises a solder feature. The solder features may be solder balls, etc. that may be attached according any known process such as a controlled heat treatment that may partially reflow one or more of solder flux or a solder ball. Alternatively, the solder features may be studs, pillars, or microbumps comprising a conductive material (e.g., solder paste). SLI 750 may further comprise one or more layer of under-bump metallization (UBM) that may, for example, include gold and/or nickel. As further illustrated in FIG. 10, system 1050 further includes a heat sink 1099 that is located over both IC chip 871, 872 and also over optical waveguide 320.

With photonic structures integrated into a package interposer as described herein, chip-to-chip communication signal frequency may be increased beyond what is possible for electrical routing. Furthermore, digital modulation schemes, such as QAM4 and Multiple Access (e.g., Wavelength Division Multiple Access and Code Division Multiple Access) can be readily employed within the optical domain to further increase data transfer rate/bandwidth between IC chips.

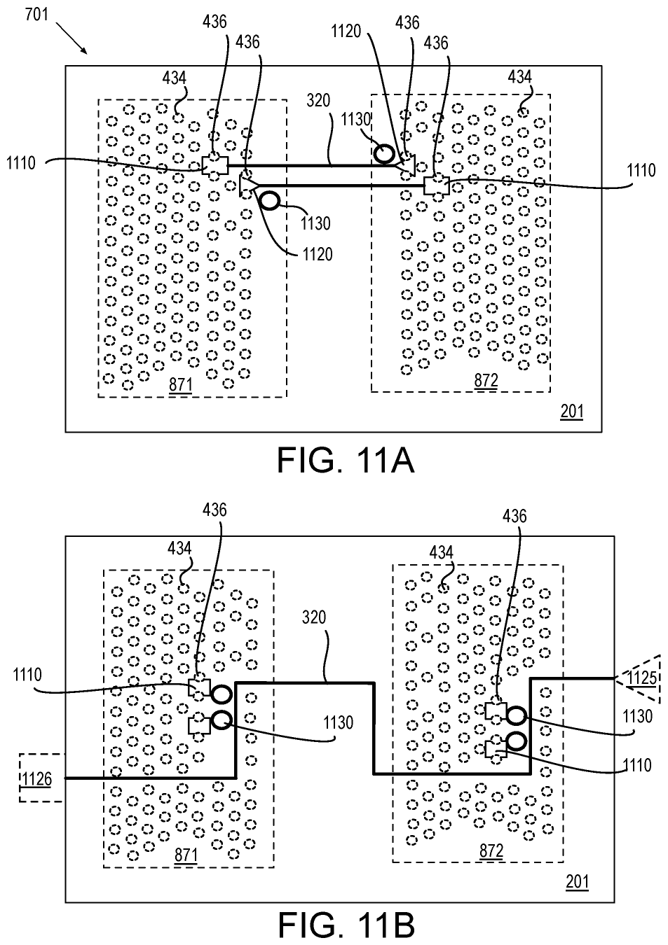

FIGS. 11A and 11B illustrate plan views of SiPh optical routing within package interposer 701, in accordance with some embodiments. A footprint of IC chip 871 and IC chip 872 over substrate core 201 is illustrated in dashed line. FIG. 11A depicts an exemplary shoreline die-to-die communication architecture using hybrid photodetectors 1110 and hybrid lasers 1120. In this example, there are a plurality of optical waveguides 320 traversing a distance over package interposer 701 between IC chip 871 and IC chip 872. Each one of the waveguides 320 is optically coupled to a PD 1110 and to a laser 1120. Each of PD 1110 and laser 1120 is electrically coupled to IC chip 871 or 872 through electrical vias 436. The remaining vias 434 electrically interconnect to IC chips 871, 872 through the interposer to SLI interfaces (not depicted). Micro-ring oscillators 1130 may also be implemented as a means for IC chips 871, 872 to modulate the optical laser signal. In this example, no chip-level or package-level optical fiber connections are needed.

FIG. 11B illustrates another example where optical waveguide 320 routes around through-vias (coupled to vias 434 illustrated in dashed line) from an off-interposer laser source 1125 to micro-ring oscillators 1130 located under each of IC chips 871 and 872. Each micro-ring oscillator 1130 is coupled to one or more PDs 1110, which are electrically coupled to one of the IC chips 871, 872 (e.g., through vias 436). Hence, FIG. 11B is an example of how, with wavelength division multiplexing, IC chips 871, 872 may be assembled on top of package-level SiPh circuitry so that IC chips 871, 872 can receive optical signals via MROs 1130 that are optically coupled to a single, shared optical waveguide 320. Although PDs 1110 are illustrated, PDs 1110 are not essential. As was noted for the shoreline example in FIG. 11A, IC chips 871, 872 can modulate optical signals through MROs 1130 for chip-to-chip communication through shared optical waveguide 320. In some examples, there is only a single, package-level optical fiber connection to laser source 1125. However, an additional fiber array connection may further optically interconnect waveguide 320 to another off-interposer component 1126.

FIG. 15 illustrates a mobile computing platform and a data server machine employing package routing with integrated SiPh structures, for example as described elsewhere herein. The server machine 1506 may be any commercial server, for example including any number of high-performance computing platforms disposed within a rack and networked together for electronic data processing, which in the exemplary embodiment includes a packaged monolithic SoC. The mobile computing platform 1505 may be any portable device configured for each of electronic data display, electronic data processing, wireless electronic data transmission, or the like. For example, the mobile computing platform 1505 may be any of a tablet, a smart phone, laptop computer, etc., and may include a display screen (e.g., a capacitive, inductive, resistive, or optical touchscreen), a chip-level or package-level integrated system 1510, and a battery 1515.

As a system component within the server machine 1506, package 1550 may include a memory block (e.g., RAM) and a processor block (e.g., a microprocessor, a multi-core microprocessor, baseband processor, or the like) interconnected through an RDL routing structure that further includes an integrated SiPh optical waveguide. Package 1550 may include one or more of a power management integrated circuit (PMIC), RF (wireless) integrated circuit (RFIC) including a wideband RF (wireless) transmitter and/or receiver (TX/RX), and memory interconnected through an RDL routing structure, which may be further interconnected onto a host board within either server 1506 or mobile device 1505.

Functionally, a PMIC may perform battery power regulation, DC-to-DC conversion, etc., and may therefore an input coupled to battery 1515 and an output providing a current supply to other functional modules. RFIC may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

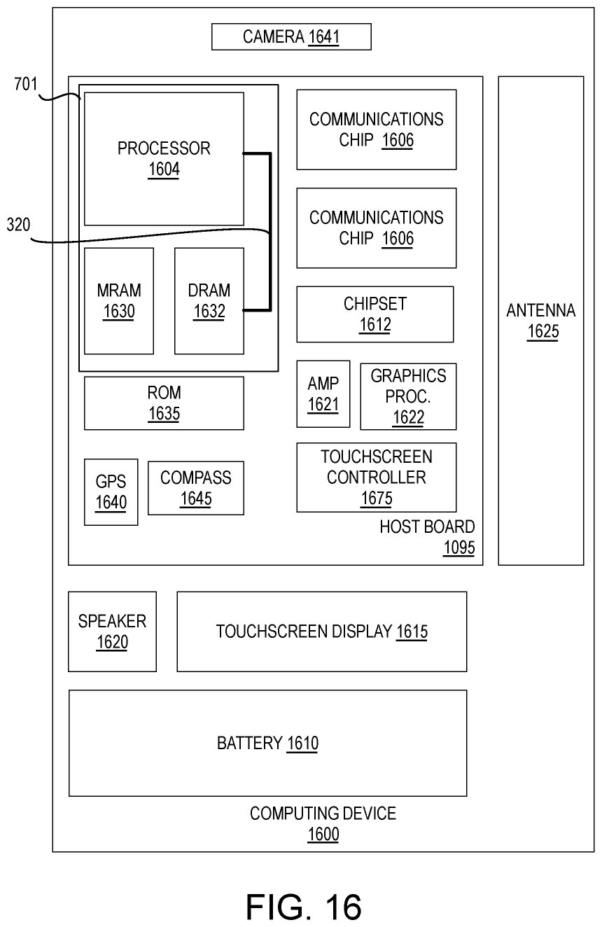

FIG. 16 is a functional block diagram of an electronic computing device, in accordance with some embodiments. Computing device 1600 may be found inside platform 1505 or server machine 1506, for example. Device 1600 further includes host board 1095 hosting a number of components, such as, but not limited to, a processor 1604 (e.g., an applications processor. Processor 1604 is attached to package interposer 701 that is electrically coupled to host board 1095 by SLI features, for example as described elsewhere herein. In some examples, package interposer 701 includes optical waveguide 320 routed around RDL features, for example as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1606 may also be physically and/or electrically coupled to processor 1604 within a PoP assembly. Depending on its applications, computing device 1600 may include other components that may or may not be physically and electrically coupled to motherboard 1602. These other components include, but are not limited to, volatile memory (e.g., DRAM 1623), non-volatile memory (e.g., MRAM 1630, flash ROM 1635), a graphics processor 1622, a chipset 1612, an antenna 1625, touchscreen display 1615, power amplifier 1621, global positioning system (GPS) device 1640, compass 1645, speaker 1620, camera 1641, and a mass storage device (such as hard disk drive, solid-state drive (SSD), compact disk (CD), digital versatile disk (DVD), and so forth), or the like.

Communication chips 1606 may enable wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1606 may implement any of a number of wireless standards or protocols, including but not limited to those described elsewhere herein. As discussed, computing device 1600 may include a plurality of communication chips 1606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In first examples, a microelectronic device package interposer comprises metallization features comprising first interfaces on a first side of the interposer, and second interfaces on a second side of the interposer. The first interfaces are to couple with an integrated circuit (IC) chip through first-level interconnect features, and the second interfaces are to couple with a host component through second-level interconnect features. The interposer comprises photonic features comprising one or more optical waveguides of predominantly silicon, wherein the optical waveguides are on the first side of the interposer and are to couple with the IC chip.

In second examples, for any of the first examples the interposer comprises a core with a plurality of electrical through-vias extending through a thickness of the core. The metallization features comprise one or more first metallization features embedded within a first dielectric material on the first side of the interposer. The first metallization features are in contact with the electrical through-vias. The metallization features comprise or more second metallization features embedded within a second dielectric material on the second side of the interposer. The second metallization features are in contact with the electrical through-vias. The optical waveguides route around the electrical through-vias.

In third examples, for any of the first through second examples the first dielectric material is also between the waveguides and the core.

In fourth examples, for any of the first through third examples the first dielectric comprises silicon and at least one of oxygen and nitrogen, and the second dielectric comprises an organic polymer.

In fifth examples, for any of the second through fourth examples the core is glass or monocrystalline silicon.

In sixth examples, for any of the second through fourth examples the core is monocrystalline silicon, and the waveguides comprise monocrystalline silicon.

In seventh examples, for any of the fifth examples the core is glass, and the waveguides comprise polycrystalline silicon.

In eighth examples, for any of the first through seventh examples the interposer further comprises a micro-ring resonator, micro-ring oscillator, Mach-Zhender interferometer, or optical modulator comprising a length of the waveguides.

In ninth examples, an integrated circuit (IC) device package comprises the package interposer of any of the first through eighth examples, a first IC chip coupled to first ones of the first interfaces through the first level interconnect features, and a dielectric material over the interposer and adjacent to at least an edge of the first IC chip.

In tenth examples, for any of the ninth examples the package further comprises a second IC chip adjacent to first IC chip, the second IC chip coupled to second ones of the first interfaces through the first level interconnect features, and one or more of the waveguides optically coupling the first IC chip to the second IC chip.

In eleventh examples, for any of the ninth through tenth examples the package further comprises a photodetector or a laser attached to one or more of the waveguides.

In twelfth examples, for any of the eleventh examples terminals of the photodetector or the laser are coupled to the first IC chip or the second IC chip through one or more of the first metallization features.

In thirteenth examples, a system comprises the IC device package of any one of the ninth through twelfth examples, and a host component electrically coupled to the second interfaces through the second-level interconnect features.

In fourteenth examples, for any of the thirteenth examples the first IC chip comprises microprocessor circuitry to execute instructions.

In fifteenth examples, for any of the fourteenth examples the second IC chip comprises memory circuitry to store one or more bit values.

In sixteenth examples, a method of fabricating an integrated circuit package interposer comprises receiving a core comprising a plurality of electrical through-vias extending through a thickness of the core. The method comprises forming, over a first side of the core, one or more optical waveguides comprising predominantly silicon. The method comprises forming a first dielectric material over the optical waveguides, and forming first metallization features through the first dielectric material, wherein at least one of the first metallization features contacts at least one of the through-vias and terminates at a first interface. The method comprises forming, over a second side of the core, second metallization features within a second dielectric material, wherein at least one of the second metallization features contacts at least one of the through-vias and terminates at a second interface.

In seventeenth examples, for any of the sixteenth examples the method comprises attaching a first chip comprising an integrated circuit (IC) to first ones of the first interfaces, attaching a second chip comprising an IC to second ones of the first interfaces, and forming a dielectric material over the interposer and between the first and second chips.

In eighteenth examples, for any of the sixteenth through seventeenth examples the method further comprises attaching a photodetector or a laser to the optical waveguides, forming the first dielectric material over the photodetector or the laser, and forming at least one of the first metallization features to a terminal of the photodetector or the laser.

In nineteenth examples, for any of the sixteenth through eighteenth examples the method further comprises attaching the second interfaces to a host component with second-level interconnect features.

In twentieth examples, a microelectronic device assembly method comprise receiving a microelectronic device package interposer, comprising metallization features comprising first interfaces on a first side of the interposer, and second interfaces on a second side of the interposer, wherein the first interfaces are to couple with an integrated circuit (IC) chip through first-level interconnect features, and the second interfaces are to couple with a host component through second-level interconnect features, and photonic features comprising one or more optical waveguides of predominantly silicon, wherein the optical waveguides are on the first side of the interposer and are to couple with the IC chip. The method further comprises attaching the IC chip to the first interfaces with the first-level interconnect features.

In twenty-first examples, for any of the twentieth examples the method further comprises forming a dielectric material over the interposer and around at least an edge of the IC chip.

It will be recognized that principles of the disclosure are not limited to the embodiments so described, but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. A microelectronic device package interposer, comprising:
metallization features comprising first interfaces on a first side of the interposer, and second interfaces on a second side of the interposer, wherein the first interfaces are to couple with an integrated circuit (IC) chip through first-level interconnect features, and wherein the second interfaces are to couple with a host component through second-level interconnect features; and
photonic features comprising one or more optical waveguides of predominantly silicon, wherein the optical waveguides are on the first side of the interposer and are to couple with the IC chip.

2. The package interposer of claim 1, wherein:
the interposer comprises a core with a plurality of electrical through-vias extending through a thickness of the core;
the metallization features comprise:
one or more first metallization features embedded within a first dielectric material on the first side of the interposer, wherein the first metallization features are in contact with the electrical through-vias;
one or more second metallization features embedded within a second dielectric material on the second side of the interposer, wherein the second metallization features are in contact with the electrical through-vias; and
the optical waveguides route around the electrical through-vias.

3. The package interposer of claim 2, wherein the first dielectric material is also between the waveguides and the core.

4. The package interposer of claim 3, wherein the first dielectric comprises silicon and at least one of oxygen and nitrogen, and the second dielectric comprises an organic polymer.

5. The package interposer of claim 2, wherein the core is glass or monocrystalline silicon.

6. The package interposer of claim 5, wherein the core is monocrystalline silicon, and the waveguides comprise monocrystalline silicon.

7. The package interposer of claim 5, wherein the core is glass, and the waveguides comprise polycrystalline silicon.

8. The package interposer of claim 1, further comprising a micro-ring resonator, micro-ring oscillator, Mach-Zhender interferometer, or optical modulator comprising a length of the waveguides.

9. An integrated circuit (IC) device package, comprising:
the package interposer of claim 1;
a first IC chip coupled to first ones of the first interfaces through the first level interconnect features; and
a dielectric material over the interposer and adjacent to at least an edge of the first IC chip.

10. The IC device package of claim 9, wherein:
the package further comprises a second IC chip adjacent to first IC chip, the second IC chip coupled to second ones of the first interfaces through the first level interconnect features; and
one or more of the waveguides optically coupling the first IC chip to the second IC chip.

11. The IC device package of claim 9, further comprising a photodetector or a laser attached to one or more of the waveguides.

12. The IC device package of claim 11, wherein terminals of the photodetector or the laser are coupled to the first IC chip or the second IC chip through one or more of the first metallization features.

13. A system comprising:
the IC device package of claim 9; and
a host component electrically coupled to the second interfaces through the second-level interconnect features.

14. The system of claim 13, wherein the first IC chip comprises microprocessor circuitry to execute instructions.

15. The system of claim 14, wherein the second IC chip comprises memory circuitry to store bit values.

16. A method of fabricating an integrated circuit package interposer, the method comprising:
receiving a core comprising a plurality of electrical through-vias extending through a thickness of the core;
forming, over a first side of the core, one or more optical waveguides comprising predominantly silicon;
forming a first dielectric material over the optical waveguides;
forming first metallization features through the first dielectric material, wherein at least one of the first metallization features contacts at least one of the through-vias and terminates at a first interface; and
forming, over a second side of the core, second metallization features within a second dielectric material, wherein at least one of the second metallization features contacts at least one of the through-vias and terminates at a second interface.

17. The method of claim 16, further comprising:
attaching a first chip comprising an integrated circuit (IC) to first ones of the first interfaces;
attaching a second chip comprising an IC to second ones of the first interfaces; and
forming a dielectric material over the interposer and between the first and second chips.

18. The method of claim 17, further comprising:
attaching a photodetector or a laser to the optical waveguides;
forming the first dielectric material over the photodetector or the laser; and
forming at least one of the first metallization features to a terminal of the photodetector or the laser.

19. The method of claim 17, further comprising attaching the second interfaces to a host component with second-level interconnect features.

20. A microelectronic device assembly method, comprising:
receiving a microelectronic device package interposer, comprising:
metallization features comprising first interfaces on a first side of the interposer, and second interfaces on a second side of the interposer, wherein the first interfaces are to couple with an integrated circuit (IC) chip through first-level interconnect features, and the second interfaces are to couple with a host component through second-level interconnect features; and
photonic features comprising one or more optical waveguides of predominantly silicon, wherein the optical waveguides are on the first side of the interposer and are to couple with the IC chip; and
attaching the IC chip to the first interfaces with the first-level interconnect features.

21. The method of claim 20, further comprising forming a dielectric material over the interposer and around at least an edge of the IC chip.
